(19) United States
(12) Patent Application Publication
(10) Pub. No.: US 2024/0153938 A1
(43) Pub. Date: May 9, 2024

(54) INTERLEAVED HIGH SIDE AND LOW SIDE POWER TRANSISTORS WITH VARIABLE FINGER SPACING

(71) Applicant: TEXAS INSTRUMENTS INCORPORATED, Dallas, TX (US)

(72) Inventors: Neil Gibson, Freising (DE); Jerry L. Doorenbos, Tucson, AZ (US); Gerald Gradl, Kumhausen (DE); VIOLA Schaeffer, Freising (DE); Archana Venugopal, MOUNTAIN VIEW, CA (US); Henry L. Edwards, GARLAND, TX (US)

(21) Appl. No.: 18/148,658

(22) Filed: Dec. 30, 2022

Related U.S. Application Data
(60) Provisional application No. 63/423,307, filed on Nov. 7, 2022.

(51) Int. Cl. H01L 27/02; H01L 27/088; H01L 27/12

(52) U.S. Cl. CPC H01L 27/0207; H01L 27/088; H01L 27/1207

(57) ABSTRACT

An integrated circuit includes a first transistor array over a semiconductor substrate and is distributed among a first plurality of first transistor banks. A second transistor array in or over the semiconductor substrate is distributed among a second plurality of second transistor banks. A first one of the first transistor banks is located between a first one and a second one of the second transistor banks, and the second one of the second transistor banks is located between the first one of the first transistor banks and a second one of the first transistor banks. The first transistor array and the second transistor array may be alternately operated to implement a voltage-conversion integrated circuit.

### CROSS-REFERENCE TO RELATED APPLICATIONS

This application claims the benefit of U.S. Provisional Application Ser. No. 63/423,307, filed Nov. 7, 2022, which is incorporated by reference herein in its entirety.

### FIELD

This disclosure relates to the field of semiconductor manufacturing, and more particularly, but not exclusively, to management of device temperature in power transistors.

### BACKGROUND

High power transistors are used in various switching applications that include a high-side transistor and a low-side transistor. Such operation may dissipate power in the device in a manner that can compromise performance or damage the device.

### SUMMARY

The inventors disclose various devices and methods related to integrated circuits that include transistors segmented transistors that are expected to operate with greater temperature uniformity relative to baseline transistor configurations.

In one example an integrated circuit includes a first transistor array located in or over a semiconductor substrate and distributed among a first plurality of first transistor banks. A second transistor array is located in or over the semiconductor substrate and is distributed among a second plurality of second transistor banks. A first one of the first transistor banks is located between a first one and a second one of the second transistor banks, and the second one of the second transistor banks is located between the first one of the first transistor banks and a second one of the first transistor banks.

Other examples include methods of manufacturing integrated circuit devices according to the integrated circuit described above.

### BRIEF DESCRIPTION OF THE VIEWS OF THE DRAWINGS

FIGS. 1A and 1B illustrate in plan view an example integrated circuit including several transistor banks that include a number of transistor blocks;

FIG. 1C illustrates a first transistor that may be implemented by the transistor banks of FIG. 1B;

FIG. 1D illustrates a second transistor that may be implemented by the transistor banks of FIG. 1B, the transistor banks of the second transistor interleaved with the transistor banks of the second transistor;

FIGS. 2A-2E illustrate examples of transistor blocks having different density configurations;

FIG. 3 illustrates some aspects of a power conversion circuit that includes a first transistor according to, e.g. FIG. 1C and a second transistor according to, e.g. FIG. 1D;

FIG. 4A illustrates one configuration of a first modeled device having interleaved transistor banks, and FIGS. 4B and 4C illustrate computed temperature profiles of the device of FIG. 4A for different operating regimes;

FIG. 5A illustrates another configuration of a second modeled device having interleaved transistor banks, and FIGS. 5B and 5C illustrate computed temperature profiles of the device of FIG. 5A for different operating regimes; and

FIG. 6A illustrates one configuration of a third modeled device having interleaved transistor banks, and FIGS. 6B and 6C illustrate computed temperature profiles of the device of FIG. 6A for different operating regimes.

### DETAILED DESCRIPTION

The present disclosure is described with reference to the attached figures. The figures are not necessarily drawn to scale, and they are provided without implied limitation to illustrate various described examples. Several aspects of the disclosure are described below with reference to example applications for illustration. It should be understood that numerous specific details, relationships, and methods are set forth to provide an understanding of the disclosure. The present disclosure is not limited by the illustrated ordering of acts or events unless stated otherwise, as some acts may occur in different orders and/or concurrently with other acts or events. Furthermore, all illustrated acts or events may not be required to implement a methodology in accordance with the present disclosure.

Various disclosed methods and devices of the present disclosure may be beneficially applied to integrated circuits including high-power buck-boost drivers implemented in power conversion circuits. While such examples may be expected to increase the entitlement of such circuits, e.g. the safe-operating-area, or maximum operating power, no particular result is a requirement of the present invention unless explicitly recited in a particular claim.

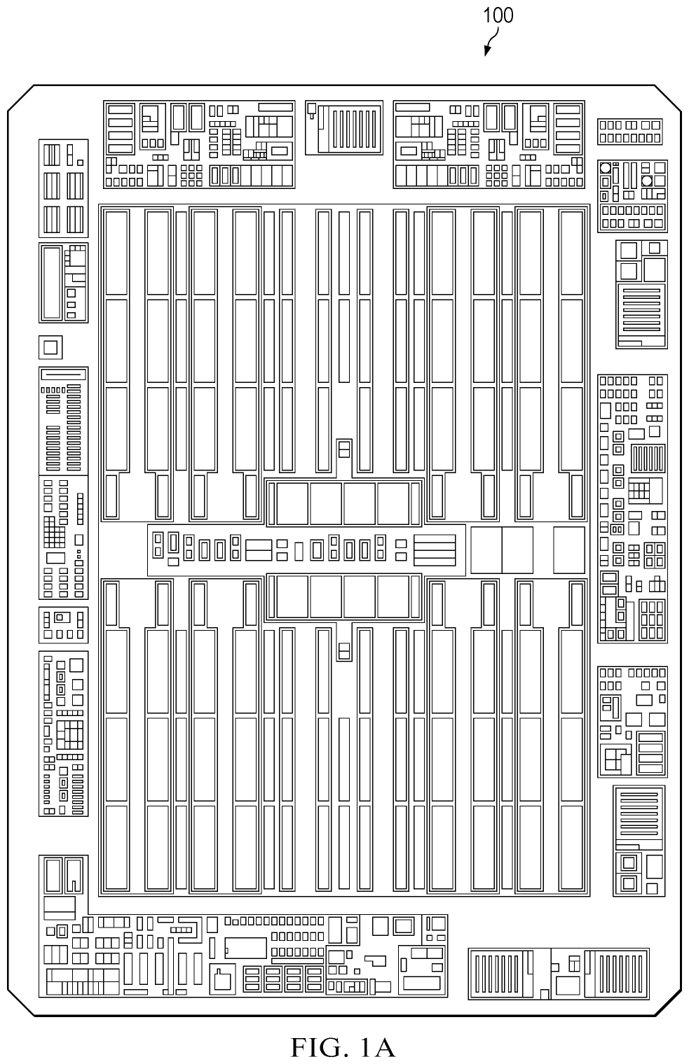

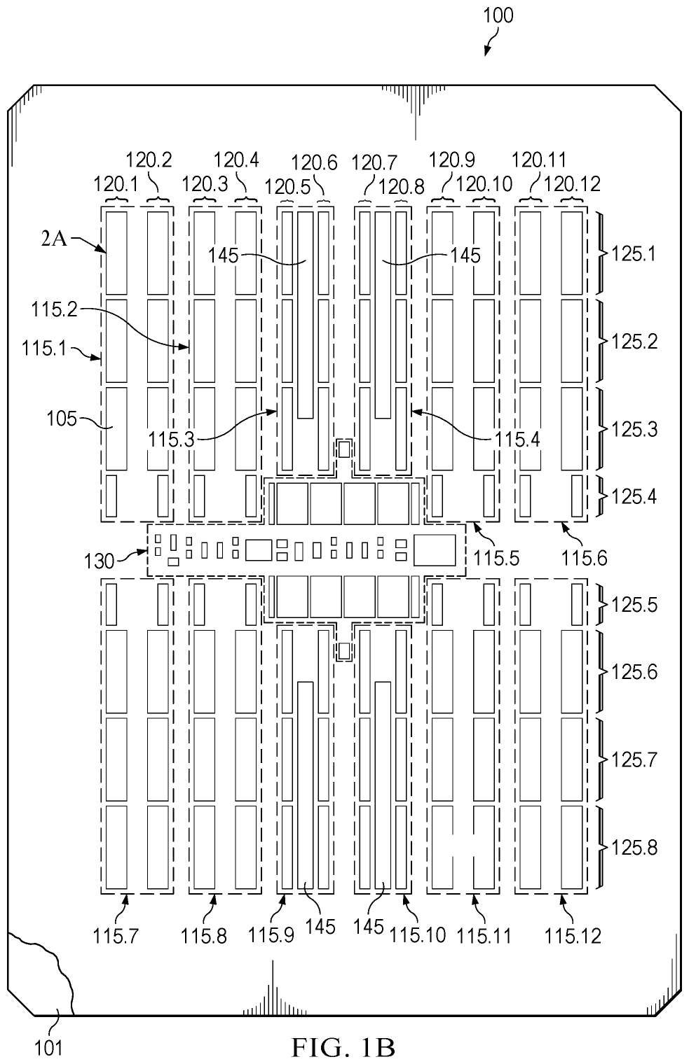

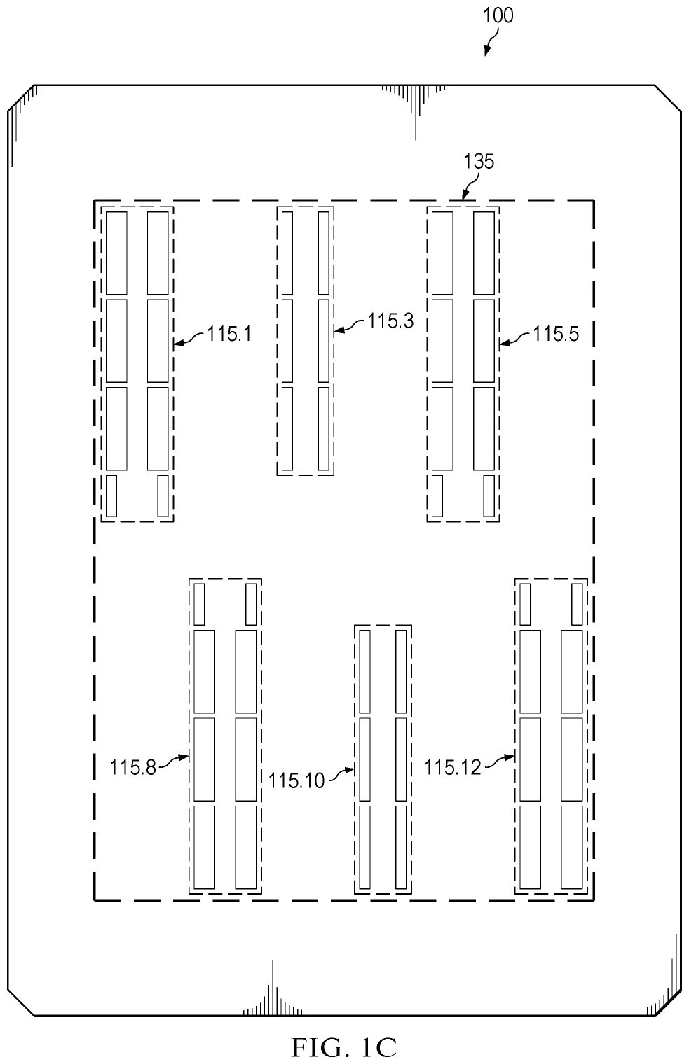

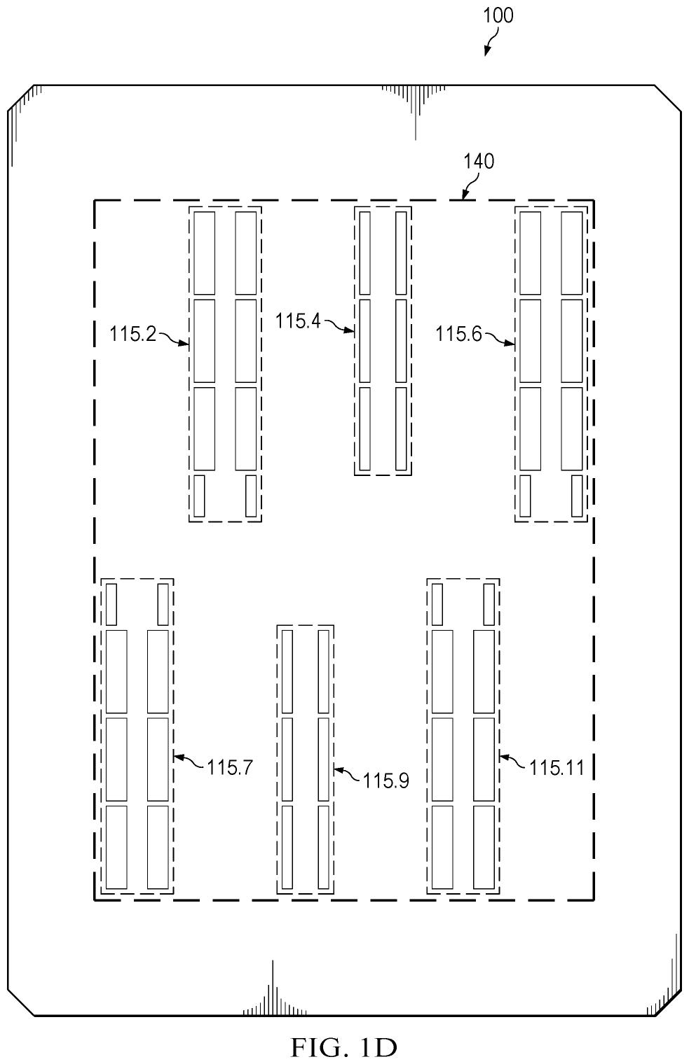

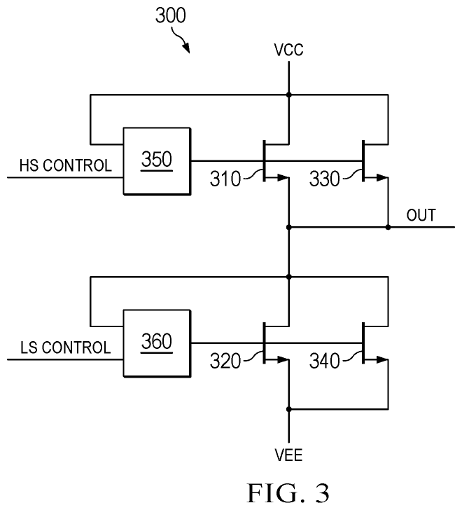

FIGS. 1A and 1B illustrate aspects of an integrated circuit (IC) 100 in plan view. FIG. 1A shows the IC 100 as rendered in a layout tool with a subset of design layers shown, and FIG. 1B shows a map of various portions of the IC 100 according to the disclosure. These figures are described concurrently, with primary attention directed to FIG. 1B. FIG. 3 illustrates an abbreviated circuit schematic that may be implemented by the IC 100 in one example, and is referred to concurrently with FIGS. 1A and 1B in the following discussion.

The IC 100 includes several transistor blocks, referred to generally as blocks 105. The blocks 105 are formed over a substrate 101, which may be, e.g. a silicon substrate, a GaN substrate or an SOI (Si over insulator) substrate. The blocks 105 are grouped in banks, referred to generally as banks 115. There are 12 banks, designated banks 115.1-115.12. In the present example, the blocks 105 are arranged in columns 120.1 through 120.12, and rows 125.1 through 125.8. The columns 120.1 . . . 120.12 may be referred collectively as columns 120, and the rows 125.1 . . . 125.8 may be referred to collectively as rows 125.

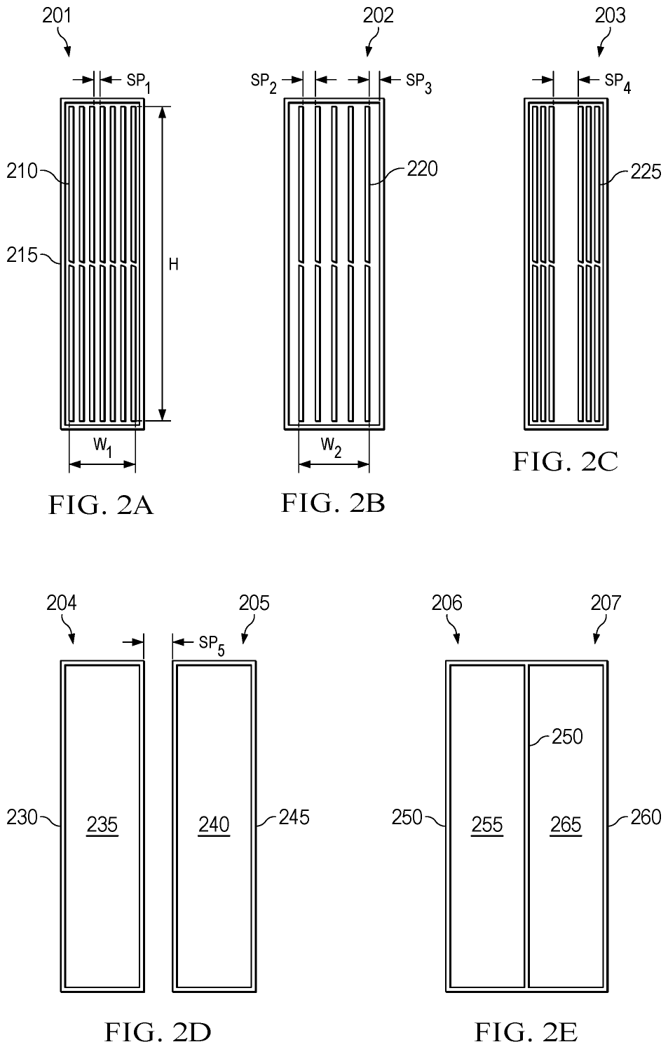

A general example of the blocks 105 is shown in FIG. 2A as block 201. The block 201 includes a plurality of segments, or fingers, 210. The fingers 210 are surrounded by isolation 215, e.g. shallow trench isolation (STI), deep trench (DT) isolation and/or junction isolation. The area surrounded by the isolation 215 is referred to as moat or active area. Such isolation allows the blocks 105 to be separately, or individually, isolated from each other. A space SP₁ refers to the lateral distance between adjacent ones of the fingers 210. A width W₁ refers to the distance from the outermost edge of a first finger 210 (left-hand side) to the outermost edge of a last finger 210 (right-hand side). While the block 201 is shown having seven fingers and height H, the blocks 105 may have any number of fingers and therefore different widths, and may have different heights.

In some examples the fingers 210 implement multiple trench gates of a vertical trench MOSFET (metal-oxide semiconductor, field-effect) transistor. While in such examples the blocks 105 are not limited to any particular implementation of a vertical trench MOSFET transistor, an example is provided by U.S. Pat. No. 9,123,802, incorporated herein by reference in its entirety. In some other examples, the fingers 210 implement multiple source/drain fingers of a drain-extended (DE) MOSFET transistor. While in such examples the block 201 is not limited to any particular implementation of a DE MOSFET transistor, an example is provided by U.S. Pat. No. 10,461,182 incorporated herein by reference in its entirety. In other examples, the block 200 may implement an NMOS or PMOS transistor, a vertical or lateral laterally-diffused MOS (LDMOS) transistor, or a bipolar transistor. The fingers 205 have a height H, which need not be the same for all the blocks 105.

FIGS. 2B and 2C show additional examples of spacing between the fingers 210. In FIG. 2B, a block 202 is illustrated including fingers 210 equally spaced apart by distance SP₂ greater than SP₁. The total number of fingers 210 in the block 202 may be the same or different than the total number of fingers 210 in other blocks the device 100, and a lateral width W₂ from the outermost edge of a first finger 210 to the outermost edge of a last finger 210 may be the same or different from the width W₁. In FIG. 2C, a block 203 is illustrated including two groups of fingers 230. The fingers 210 are equally spaced apart in the two groups, and the two groups are spaced apart by space SP₄ that is greater than the line-to-line spacing within the groups. Further, FIG. 2B has a moat spacing SP₃ that is larger than a similar spacing in FIG. 2A, and illustrates that different ones or groups of the transistor blocks 105 may have a different moat spacing than others of the transistor blocks 105. The total number of fingers 210 in the block 203 may be the same or different than the total number of fingers 210 in other blocks in the device 100.

FIG. 2D illustrates blocks 204 and 205 with the fingers 210 omitted for clarity. The block 204 includes isolation 230 that surrounds an internal area 235 that may be referred to as a moat or active area in which the fingers 210 are formed. The block 205 includes isolation 240 that surrounds another internal area 245. The isolations 204, 205 laterally spaced apart by space SP₅. FIG. 2E illustrates blocks 206 and 207 again with the fingers 210 omitted for clarity. An isolation 250 surrounds an internal area 255 (e.g. moat) on three sides, and an isolation 260 surrounds an internal area 265 on three sides. An isolation 250 is shared between the internal areas 255, 265, in effect resulting moat spacing of zero (e.g. SP₅=0).

Thus FIGS. 2A-2E illustrate examples of design variations that may be used to form transistor blocks 105 having different densities in local areas of the device 100. The illustrated examples are not exclusive of other ways to vary the finger density, and each illustrated example may be used alone or in combination with other illustrated or non-illustrated examples.

In addition to the spacing examples of FIGS. 2A-2E, in some examples some transistor blocks 105 in the device 100 may have a same voltage rating, and in some examples some blocks 105 have a first voltage rating and others have a different second voltage rating. The voltage rating of a transistor block 105 may be a function of different gate oxide thickness, field oxide thickness, drain extension, channel length, and source and drain implants, among several parameters. Transistor blocks 105 having different voltage ratings may also have different power dissipation characteristics. Thus the voltage rating is another variable that may be used to manage local power dissipation on the device 100 to effectively manage heat flow and peak temperature across the substrate 101.

Referring again to FIG. 1B, it can be seen that the blocks 105 in rows 125 . . . 125.3 and 125.6 . . . 125.8 have a first height, and the blocks 105 in rows 125.4 and 125.5 have a smaller second height. It can also be seen that the blocks 105 in columns 120.1, 120.3, 120.10 and 120.12 have a first width, excepting those blocks 105 in rows 125.4 and 125.5. The blocks 105 in columns 120.2, 120.4, 120.9 and 120.11 have a smaller second width, excepting those blocks 105 in rows 125.4 and 125.5. And the blocks 105 in columns 120.5 . . . 120.8 have a smaller third width. The different widths of the blocks may be due to a different spacing between the fingers 210, a different width of the fingers 210 (FIG. 2A), or a different number of the fingers 210 in the subject block 105.

Referring to FIG. 3, a circuit 300 may be configured to drive a power device (not shown), and includes transistors 310 and 320. In this example, the circuit 300 implements a voltage converter circuit, e.g. a boost converter, and the transistor 310 is a high-side (HS) transistor and the transistor 320 is a low-side (LS) transistor. One half of the banks 115 (FIG. 1) are connected to implement the HS transistor 310 and one half of the banks 115 are connected to implement the LS transistor 320. A transistor 330 provides a signal proportional to the current flow through the HS transistor 310 to active circuitry 350 that also receives an HS control signal to operate the HS transistor 310. Similarly, a transistor 340 provides a signal proportional to the current flow through the LS transistor 320 to active circuitry 360 that also receives an LS control signal to operate the LS transistor 320. Active circuitry may contain, e.g. logic and other active components that interface the circuit 300 to other electronic devices, and control the transistors 310, 320 in response to the signals provided by the transistors 330 and 340. An example of a boost converter circuit that may employ switches such as the HS transistor 310 and the LS transistor 320 is provided by U.S. Pat. No. 10,069,416, incorporated herein by reference in its entirety.

FIGS. 1C and 1D illustrate one example of such a configuration of the banks 115. In FIG. 1C, banks 115.1. 115.3, 115. 5, 115.8, 115.10 and 115.12 are shown, indicating that these banks are configured to operate together as the transistor 310. For brevity and without implied limitation these banks 115 may be referred to as “high-side banks” 115, and this grouping of banks is referred to as a transistor array 135. In FIG. 1D, banks 115.2. 115.4, 115. 6, 115.7, 115.9 and 115.11 are visible, indicating that these banks are configured to operate together as the transistor 320. For brevity and without implied limitation these banks 115 may be referred to as “low-side banks” 115, and this grouping of banks is referred to as a transistor array 140. Configuration of the high-side banks 115 to operate as the HS transistor 310 may include appropriate interconnection of gates, sources and drains of the individual blocks 105 of the high-side banks 115. Similarly, configuration of the low-side banks 115 to operate as the LS transistor 320 may include appropriate interconnection of gates, sources and drains of the individual blocks 105 of the low-side banks 115.

In the example of FIGS. 1C and 1D, the banks 115.1 . . . 115.6 are interleaved with each other, or alternate between high-side bank and low-side bank. Similarly the banks 115.7 . . . 115.12 alternate between high-side bank and low-side bank. In the present example, the top row of banks 115 begins with a high-side bank 115, and the bottom row of banks 115 begins with a low-side bank 115. Thus each of the high-side banks 115 has three low-side banks as nearest neighbor banks, and each of the low-side banks 115 has three high-side banks as nearest neighbor banks. This configuration may be referred to as “offset-interleaved”.

Referring again to FIGS. 1A, and 1B instances of the blocks 105 are optionally omitted from a central region 130 that includes the intersections of rows 125.4 and 125.5 and columns 120.5 . . . 120.8. Utility of the central region 130 is described below.

During operation, the various components of an IC dissipate power, resulting in an operating temperature greater that an off-state (quiescent) temperature. Generally the operating temperature varies across the IC substrate (e.g. die), and may result in localized hot spots. In some operating conditions, hot spots can exceed a temperature at which physical damage occurs, e.g. by enabling parasitic devices that draw a destructive current through a portion of the IC, or exceeding a melting point of a material layer. As described further below, features of the IC 100 may result in a more uniform temperature distribution than some conventional comparative devices, reducing the likelihood of hot spots and increasing the power entitlement of the device.

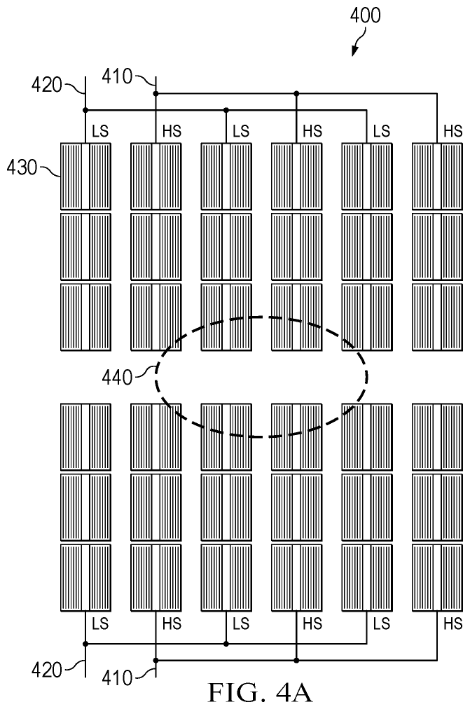

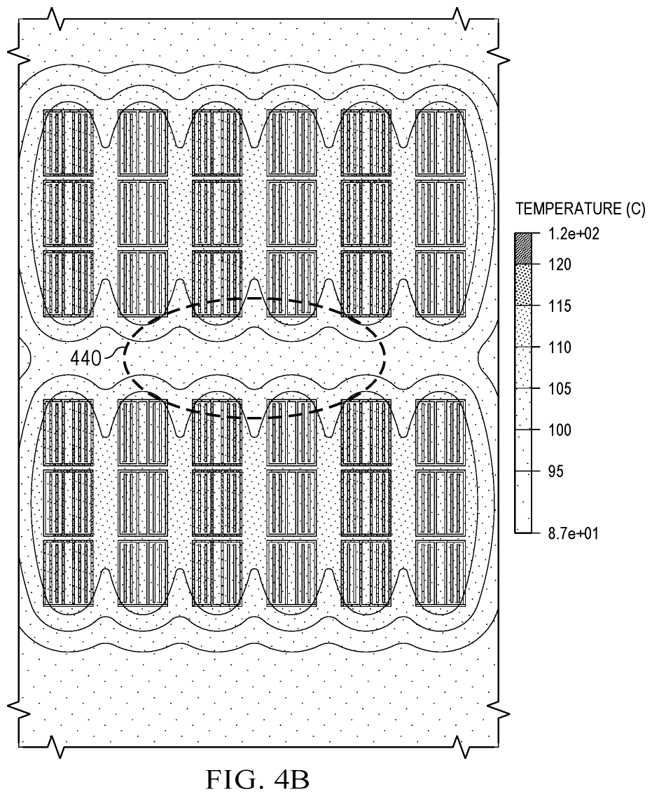

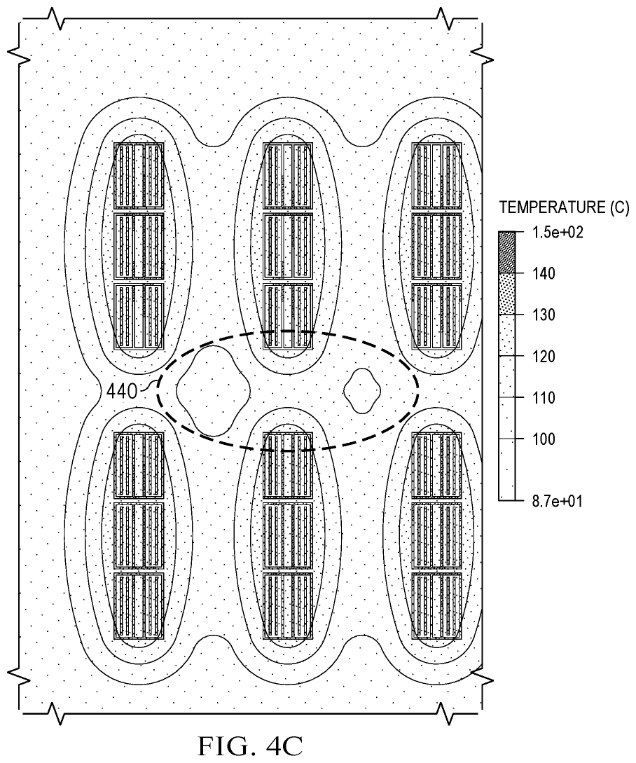

FIG. 4A illustrates a model device 400 used to computationally estimate temperature across a device die according to one configuration of transistor banks. The model device 400 includes six high-side banks 410 representing implementation of the HS transistor 310 in the circuit 300 (FIG. 3). The high-side banks 410 are interleaved with six low-side banks 420 representing implementation of the LS transistor 320, but not offset-interleaved. Each of the banks 410 and 420 includes six blocks 430. The blocks 430 include transistors implemented with evenly-spaced fingers, all having a same length, and all the transistors have a same voltage rating.

FIG. 4B shows a temperature map of the modeled device 400 when the high-side banks 410 and the low-side banks 420 are modeled as alternately operated with a 50 W signal at a frequency, e.g. 20 kHz, representative of an operating buck-boost converter as exemplified by the circuit 300. Such a stimulus is referred to as a “transient signal”. The modeled temperature profile is relatively uniform across the top half of the device 400 and across the bottom half of the device 400, with the temperature of the low-side banks 420 elevated with respect to the high-side banks 410. A horizontal region between the upper-half of the model device 400 and the lower-half of the model device 400 is relatively cooler than the high-side and 410 and the low-side banks 420. A central region 440 has a relatively uniform temperature between 90° C. and 100° C. The maximum computed temperature within the device 400 is computed to be about 123° C. in response to the transient signal, while the minimum temperature is below 90° C. at the upper and lower edges of the model device, consistent with radiant or conductive heat loss at the periphery of the device 400.

FIG. 4C shows a temperature map of the modeled device 400 when only the high-side banks 410 are energized with constant 50 W signal referred to as “steady state” signal. The modeled temperature shows six regions corresponding to the high-side banks 410, each having a temperature profile with a broad local maximum with respect to the low-side banks 420 and peripheral regions. The high-side banks 410 on the right-hand side of the modeled substrate have a higher temperature due to an insufficient distance to the edge of the substrate over which to radiate or conduct heat from this portion of the device. The maximum computed temperature within the device 400 is computed to be about 155° C. in response to the steady state signal. The computed temperature in the central region 440 is comparable to that produced by the transient signal.

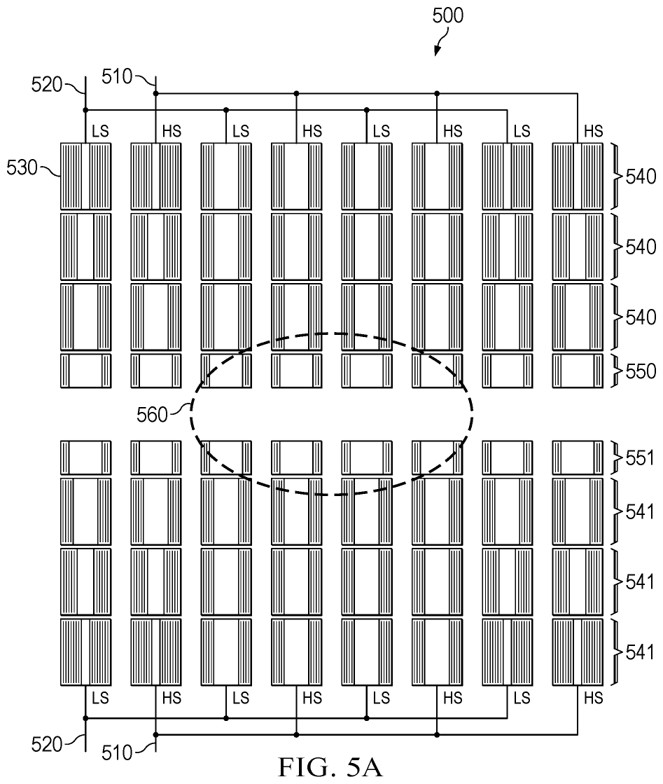

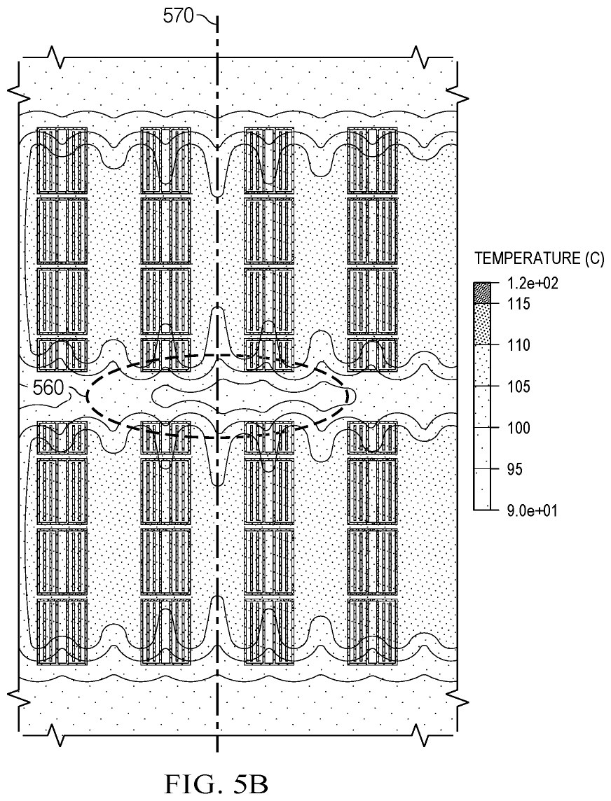

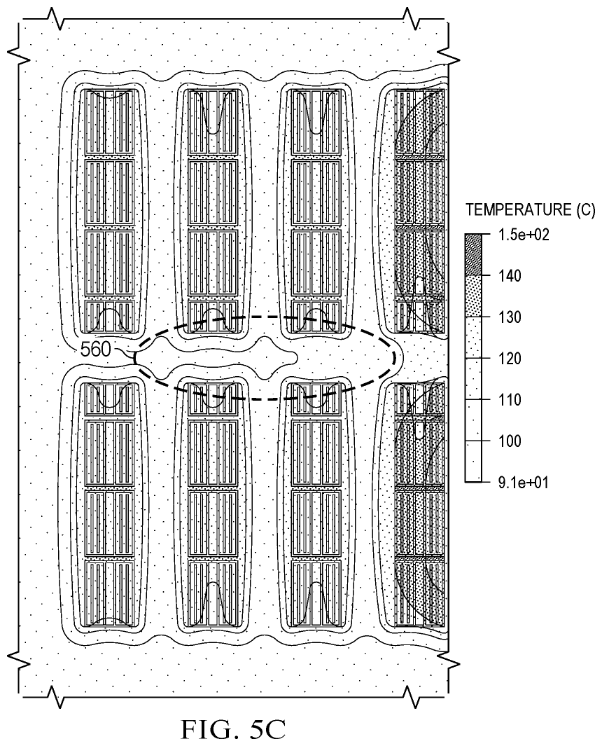

FIG. 5A illustrates a model device 500 used to computationally estimate temperature across a device die according to another configuration of transistor banks. The model device 500 includes eight high-side banks 510 representing implementation of the HS transistor 310 in the circuit 300 (FIG. 3). The model device 500 also includes eight low-side banks 520 representing implementation of the LS transistor 320. Similar to the model device 400 the banks 510, 520 are interleaved but not offset-interleaved, and all the transistors have a same voltage rating. Each of the banks 510 and 520 includes eight blocks 530. The blocks 530 include three rows 540 at the top having a first height, and one row 550 having a second height one half of the first height. The blocks 530 further include three rows 541 at the bottom having the first height, and one row 551 having the second height. In contrast to the model device 400, the number of fingers is not the same for all the blocks 530. For example, the number of fingers in the blocks 530 generally decreases from the left side toward the center, and from the right side toward the center. The decrease is effected by a configuration exemplified by the example block 202 (FIG. 2C), in which a contiguous subset of some of the fingers 210 are deleted relative to the example block 200 (FIG. 2A). Further, the number of fingers in the blocks 530 generally decreases from the top side toward the center and from the bottom side toward the center. Thus the density of fingers is greatest at the corners of the device 500 and least at a central region 560.

FIG. 5B shows a temperature map of the modeled device 500 when the high-side banks 510 and the low-side banks 520 are alternately stimulated with the transient signal described previously. While the modeled temperature profile is still relatively horizontally uniform across the top half and the bottom half of the device 500, the profile is slightly cooler along a vertical midline 570 as compared to the modeled device 400, and the temperature in the central region 560 is slightly cooler than for the modeled device 400, about 90° C. This reduction of temperature is attributed to the lower power dissipation of the high-side banks 510 and low-side banks 520 toward the center of the model device 500 due to the lower density of fingers in the blocks 530 in that part of the device 500. The maximum computed temperature within the device 500 is computed to be about 120° C. in response to the transient signal, about 3° C. cooler than for the modeled device 400.

FIG. 5C shows a temperature map of the modeled device 500 when only the high-side banks 510 are stimulated with the steady state signal. The modeled temperature now shows eight regions corresponding to the high-side banks 510, each having a temperature profile with a local maximum with respect to surrounding temperatures. The high-side banks 510 on the right-hand side of the modelled substrate again have a higher temperature due to the lack of area to shed heat. Even so, the maximum computed temperature within the device 500 is computed to be about 150° C. in response to the steady state signal, about 5° C. cooler than for the modeled device 400.

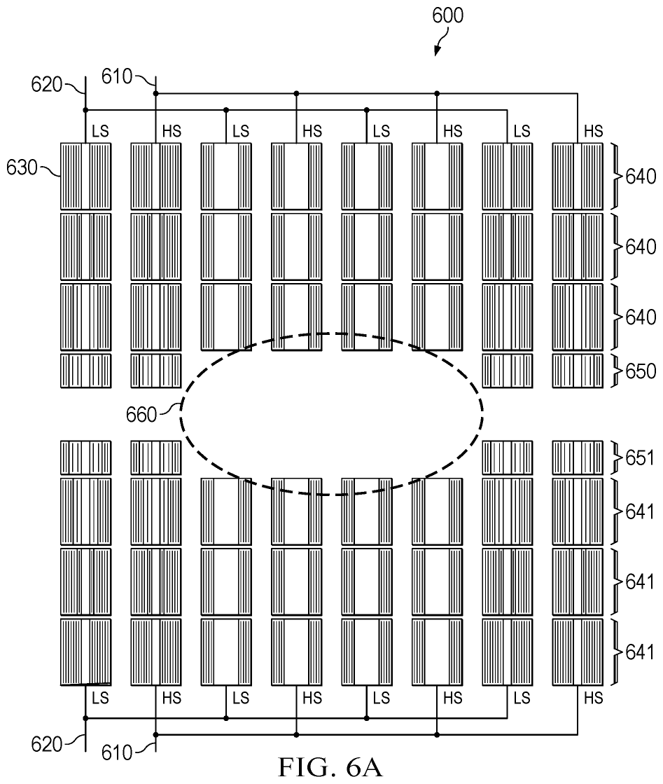

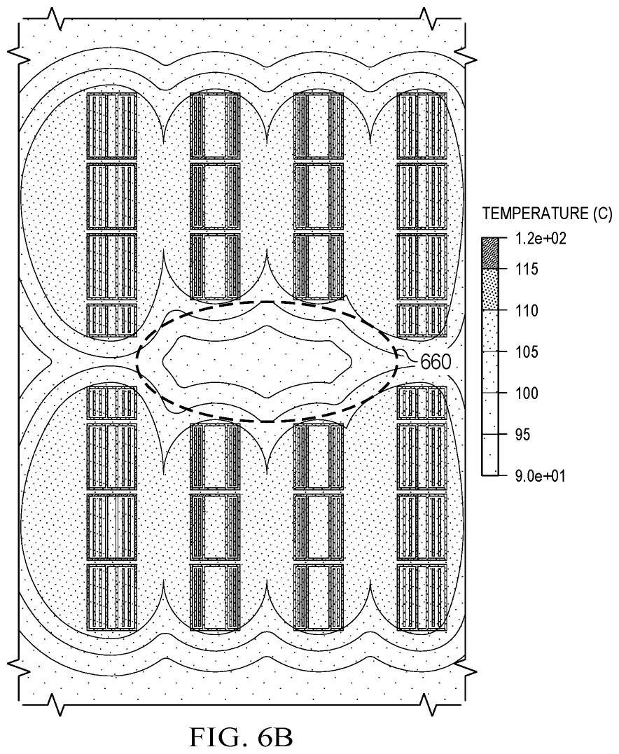

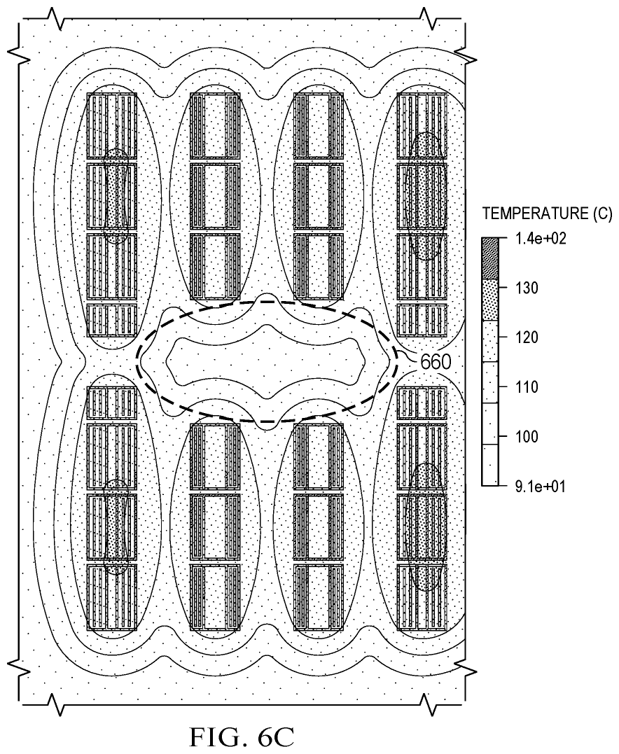

FIG. 6A illustrates yet another model device 600 used to computationally estimate temperature across a device die according to another configuration of transistor banks. The model device 600 again includes eight high-side banks 610 representing implementation of the HS transistor 310 in the circuit 300 (FIG. 3), and eight low-side banks 620 representing implementation of the LS transistor 320. Again the banks 610, 620 are interleaved but not offset-interleaved, and all the transistors have a same voltage rating. Each of the banks 610 and 620 includes eight blocks 630. As was described for the model device 500, the model device 600 also includes three rows 640 of the blocks 630 at the top having a first height, and one row 650 of the blocks 630 having a second height one half of the first height. The blocks 630 further include three rows 641 of the blocks 630 at the bottom having the first height, and one row 651 of the blocks 630 having the second height. Similar to the model device 500, the number of fingers is not the same for all the blocks 630. In this example, the density of fingers in the blocks 630 changes in two ways. In a first manner, the number of fingers in the blocks 630 generally decreases from the left side toward the center, and from the right side toward the center. The decrease is effected by a configuration exemplified by the example block 202 (FIG. 2C), in which a contiguous subset of some of the fingers 210 are deleted relative to the example block 200 (FIG. 2A). In a second manner, the number of fingers in the blocks 630 generally decreases from the top side toward the center and from the bottom side toward the center. The decrease in this direction is effected by a configuration exemplified by the example block 201 (FIG. 2B), in which a noncontiguous subset of some of the fingers 210 are deleted relative to the example block 200 (FIG. 2A), e.g. deleting every other finger. In addition to the reduction of finger density, blocks are omitted from the rows 650 and 651 for the four central columns. Thus the density of fingers decreases from the periphery of the model device 600 toward the center, in both the horizontal and vertical directions in a more pronounced fashion than for the model device 500.

FIG. 6B shows a temperature map of the modeled device 600 when the high-side banks 610 and the low-side banks 620 are alternately stimulated with the transient signal described previously. The modeled temperature profile across the top half and the bottom half of the device 600 is similar to that of FIG. 5B, e.g. relatively uniform. However, the central region 660 is significantly cooler relative to the central region 560, e.g. about 10° C. cooler. Moreover the temperature within the central region 660 is relatively uniform. The maximum computed temperature within the device 600 is computed to be about 118° C. in response to the transient signal, about 2° C. cooler than for the modeled device 500.

FIG. 6C shows a temperature map of the modeled device 600 when only the high-side banks 610 are stimulated with the steady state signal. The modeled temperature is qualitatively similar to the temperature map of the modeled device 500 (FIG. 5C), with the addition of the cooler central region 660. The maximum computed temperature within the device 600 is computed to be about 140° C. in response to the steady state signal, about 10° C. cooler than for the modeled device 500.

Additional simulations determined that for the modeled device 400 driven with a rectangular square pulse representative of typical device operating conditions, a maximum allowable power of operation is about 55 W, while limiting the temperature of the modeled device to 160° C. In contrast a maximum allowable power of operation of the modeled device 600 is about 64 W with similarly limited operating temperature, about a 16% increase in power entitlement relative to the modeled device 400. Additional work has determined that when the transistor banks are offset-interleaved, addition uniformity in heat dissipation, and increase in power entitlement results.

Generally, baseline devices that include a HS and LS transistor may segment each of the transistors into two portions, each portion occupying a quadrant of a device die. For example a HS transistor may have two segments occupying the top left and bottom right of the die, and the LS transistor may have two segments occupying the top right and bottom left of the die. In such implementations one of the HS transistor and the LS transistor may always be on, resulting in nearly constant power dissipation near the center of the device die. Due to thermodynamic considerations, in such devices the center of the device die can be expected to have a locally maximum temperature relative to the remaining die as heat flows from the center of the die outward to the edges of the die, and from the perimeter of the die toward the center.

In contrast to such baseline implementations, examples consistent with the disclosure reduce the density of dissipating features near the center of the device relative to the periphery of the device, This configuration results in a ring of relatively higher power dissipation around a central region of relatively lower power dissipation, in turn resulting in a more uniform temperature distribution across the device die relative to baseline. Moreover, by one or more of creating a gap between the upper and lower halves of the device, having a lower density of transistor elements near the center of the die than at the periphery of the die, and removing some dissipating features near the center of the device, a relatively cool, and relatively thermally stable, region results. Some circuit components that are thermally sensitive or benefit from operating at a nearly same temperature may be located in this central region. The operation of the overall circuit may benefit by the stability of operational parameters of such components, e.g. stable feedback signals and timing.

Returning to FIGS. 1A and 1B, various features of the modelled devices 400, 500, 600 are exemplified by the IC 100. Rows 125.1 . . . 125.3 and 125.6 . . . 125.8 include four blocks 105 having a first width at columns 120.5 . . . 120.8, four blocks 105 having a second greater width at columns 120.2, 120.4, 120.9 and 120.11, and four blocks 105 having a third greater width at columns 120.1, 120.3, 120.10 and 120.12. All the blocks in these rows have a same first height. Rows 125.4 and 125.5 each include eight blocks 105 having a fourth width at columns 120.1 . . . 120.4 and 120.9 . . . 120.12. The fourth width is smaller than the first and second widths and in the present example is equal to the third width. The blocks 105 in the rows 125.4 and 125.5 all have a second height less than the first height, e.g. one-half of the first height. While the IC 100 shows a subset of the features exemplified by the model devices 500 and 600, other devices within the scope of the disclosure may include other such features, or may omit some of the illustrated features. Furthermore, in the example of the IC 100, the banks 115 are offset-interleaved, which is expected to provide greater power entitlement relative to alternative examples lacking this feature.

The central region 130 includes various circuit components of the circuit 300, e.g. the transistors 330 and 340. As exemplified by the central region 660 (FIG. 6B), the central region 130 may provide a relatively cool and thermally stable portion of the IC 100 at which to place circuit components for which such lower temperature and/or stability are desirable. Because the transistors 330 and 340 provide feedback regarding the current flow through the transistors 310 and 320, it may be advantageous to locate the transistors 330 and 340 in the central region 130 to benefit from that thermal environment. In some examples the transistors 330 and 340 are nominally identical, or matched. The electrical performance of such matched devices may be matched as well when the devices are operated in similar thermal environments. Other support components of the circuit 300, such as some or most of the components that implement the active circuitry 350, 360, may also be located in the central region 130, including other transistors, resistors, op-amps, and/or comparators. Furthermore, unused space, or interstices, that result from reducing the density of some of the blocks 105 may be used to place other circuit components 145, for example passive component such as capacitors, that are less sensitive to their thermal environment.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. An integrated circuit, comprising:
a first transistor array in or over a semiconductor substrate and distributed among a first plurality of first transistor banks; and
a second transistor array in or over the semiconductor substrate and distributed among a second plurality of second transistor banks,
wherein a first one of the first transistor banks is located between a first one and a second one of the second transistor banks, and the second one of the second transistor banks is located between the first one of the first transistor banks and a second one of the first transistor banks.

2. The integrated circuit of claim 1, wherein the first one of the first transistor banks includes a first number of blocks, and the second one of the second transistor banks includes a second smaller number of blocks.

3. The integrated circuit of claim 2, wherein the blocks are individually isolated.

4. The integrated circuit of claim 3, wherein the blocks include deep trench isolation structures that surround corresponding blocks.

5. The integrated circuit of claim 1, wherein
the second one of the first transistor banks is located between the second one of the second transistor banks and a third one of the second transistor banks;
the first one of the first transistor banks and the second one of the second transistor banks laterally extend over the semiconductor substrate a first distance in a first direction; and
the first one of the second transistor banks and the second one of the first transistor banks laterally extend a greater second distance in the first direction.

6. The integrated circuit of claim 1, wherein the first and second ones of the first transistor banks and the first and second ones of the second transistor banks bound a central region of the integrated circuit located directly between the first one of the second transistor banks and the second one of the first transistor banks.

7. The integrated circuit of claim 6, further comprising active circuit components configured to control the first and second transistor banks, wherein the active circuit components are located in the central region.

8. The integrated circuit of claim 1, wherein the first transistor bank is configured as a high-side transistor of a voltage converter circuit and the second transistor bank is configured as a low-side transistor of the voltage converter circuit.

9. The integrated circuit of claim 1, wherein a first spacing between sub-banks in the first one of the first transistor banks is greater than a second spacing between sub-banks in the second one of the first transistor banks.

10. The integrated circuit of claim 1, wherein the first and second transistor arrays include a plurality of isolated sub-banks, each sub-bank including a plurality of vertical trench transistor segments.

11. The integrated circuit of claim 10, wherein a first block of the first one of the second transistor banks has a first number of vertical trench transistor segments and a second block of the second one of the second transistor banks has a lesser second number of vertical trench transistor segments.

12. A method of manufacturing an integrated circuit, comprising:
forming a first transistor array in or over a semiconductor substrate and distributed among a first plurality of first transistor banks; and
forming a second transistor array in or over the semiconductor substrate and distributed among a second plurality of second transistor banks,
wherein a first one of the first transistor banks is located between a first one and a second one of the second transistor banks, and the second one of the second transistor banks is located between the first one of the first transistor banks and a second one of the first transistor banks.

13. The method of claim 12, wherein the first one of the first transistor banks includes a first number of blocks, and the second one of the second transistor banks includes a second smaller number of blocks.

14. The method of claim 13, wherein the blocks are separately isolated.

15. The method of claim 14, wherein the blocks include corresponding deep trench isolation structures that surround the corresponding blocks.

16. The method of claim 12, wherein
the second one of the first transistor banks is located between the second one of the second transistor banks and a third one of the second transistor banks;
the first one of the first transistor banks and the second one of the second transistor banks laterally extend over the semiconductor substrate a first distance in a first direction; and
the first one of the second transistor banks and the second one of the first transistor banks laterally extend a greater second distance in the first direction.

17. The method of claim 12, wherein the first and second ones of the first transistor banks and the first and second ones of the second transistor banks bound a central region of the integrated circuit located directly between the first one of the second transistor banks and the second one of the first transistor banks.

18. The method of claim 17, further comprising forming active circuit components configured to control the first and second transistor banks, wherein the active circuit components are located in the central region.

19. The method of claim 12, wherein the first transistor bank is configured as a high-side transistor of a voltage converter circuit and the second transistor bank is configured as a low-side transistor of the voltage converter circuit.

20. The method of claim 12, wherein a first spacing between sub-banks in the first one of the first transistor banks is greater than a second spacing between sub-banks in the second one of the first transistor banks.

21. The method of claim 12, wherein the first and second transistor arrays include a plurality of isolated sub-banks, each sub-bank including a plurality of vertical trench transistor segments.

22. The method of claim 21, wherein a first block of the first one of the second transistor banks has a first number of vertical trench transistor segments and a second block of the second one of the second transistor banks has a lesser second number of vertical trench transistor segments.
